(19) United States
(12) Patent Application Publication
(10) Pub. No.: US 2004/0077156 A1
(43) Pub. Date: Apr. 22, 2004

(54) Methods of defect reduction in wide bandgap thin films using nanolithography

(76) Inventors: Loucas Tsakalakos, Niskayuna, NY (US); Azar Alizadeh, Wilton, NY (US); William H. Huber, Scotia, NY (US); Patrick Malenfant, Clifton Park, NY (US); Judith Stein, Schenectady, NY (US); Fazila Seker, Clifton Park, NY (US); John B. Reitz, Clifton Park, NY (US); Surya P. Ganti, Guilderland, NY (US); Pradeep Sharma, Saratoga Springs, NY (US)

Correspondence Address: DOUGHERTY, CLEMENTS & HOFER, 1901 ROXBOROUGH ROAD, SUITE300, CHARLOTTE, NC, 28211, US

(21) Appl. No.: 10/273,926

(22) Filed: Oct. 18, 2002

(51) Int. Cl. H01L 21/20; H01L 21/36; H01L 21/28; H01L 21/44

(52) U.S. Cl. 438/479; 438/503

(57) ABSTRACT

Methods of fabricating a semiconductor film with reduced defects comprising lithographically defined nanoscale features patterned into an underlying layer. A semiconductor film is then nucleated within the plurality of nanoscale features. The nanoscale features are aligned with specific crystallographic axes to allow for controlled growth rates. A semiconductor film produced with a greater than four orders of magnitude decrease in the threading dislocation density and thus improved optical and electrical transport properties. The invention applies to wide bandgap semiconductor films, however, also applies to any film-substrate combination where significant lattice and thermal expansion misfit occurs.

### BACKGROUND OF THE INVENTION

1. Field of the Invention

The present invention relates generally to the field of microelectronic devices and fabrication methods. More particularly, the present invention relates to reducing the dislocation density in an overgrown film by patterning nanoscale features in a semiconductor layer.

2. Description of the Related Art

Semiconducting thin films are commonly used as the active element of microelectronic devices. The mechanisms responsible for their microstructure and the effect of their defect structure on electronic properties are the object of widespread scientific and technological investigation. A major problem in fabricating thin films is producing semiconductor layers having low defect densities. One factor that affects defect density is the substrate on which the thin film is grown. If the degree of lattice and thermal expansion mismatch is high, the use of conventional fabrication techniques will produce films with a significant amount of extended defects in the form of threading dislocations (TD).

The preparation of defect-free semiconductor materials is easier when a substrate of the same material is used (homoepitaxy). However, often times this is not possible and defects are created during the preparation of the semiconductor material at the interface between the semiconductor and the substrate, as a result of the lattice and thermal mismatch between the semiconductor and the substrate materials (heteroepitaxy). Buffer layers and other multi-layer schemes are often used to form a transition between the substrate and the semiconductor layer, but these have proven insufficient in many cases to produce the desired reduction in defect density. Many defects propagate perpendicular to the substrate/layer interface, without stopping as a film is grown thicker.

Gallium nitride and silicon carbide thin films are typically grown on single crystal substrates, such as sapphire or silicon carbide, since these substrates have been found to produce a high quality material. In the case of gallium nitride on sapphire, the lattice misfit may be about 14.6%, leading to a threading dislocation density of about 10⁹ to about 10¹¹ cm⁻². Remarkably, for LED structures, these defect levels have been found to have a minimal effect on the performance of the device, most likely due to carrier localization. On the other hand, laser structures and electronic circuitry for high-temperature applications will be affected by their presence, both in terms of output and lifetime. Similar issues apply to silicon carbide light emitting and electronic devices.

One conventional approach for reducing defect density levels in wide bandgap thin films involves depositing a mask layer, such as silicon oxide or silicon nitride, onto a buffer layer such as gallium nitride or aluminum nitride. The mask layer includes at least one opening, though typically an array of openings of a given width and pitch, created by standard photolithography that exposes at least one portion of the underlying buffer layer. The desired gallium nitride film is subsequently grown through the mask. This technique is referred to as the epitaxial lateral overgrowth (ELO) technique. Due to the low sticking coefficient of growth species on the mask layer, the gallium nitride film preferentially nucleates on the underlying substrate in the openings and grows in the direction normal to the surface of the substrate, but then proceeds in the direction parallel to the surface of the substrate once the film has reached the top of the mask layer. The film is grown until it coalesces on the mask to form a single continuous layer. In order to further reduce defect densities, a second mask may be deposited on the laterally overgrown gallium nitride layer. The second mask layer again includes at least one opening, though typically an array openings of a given width and pitch, the at least one opening being offset from the underlying first deposited mask layer. The gallium nitride is then laterally grown over the openings of the second mask, forming a single layer. The defect density of the second single layer of gallium nitride is lower than that of the first single layer.

A second conventional technique for reducing defect densities in gallium nitride and other wide bandgap films involves growing gallium nitride on a very thin silicon nitride film that has not coalesced on the surface of a substrate. The silicon nitride, grown by flowing silane and ammonia for a brief amount of time (seconds to minutes), is in the form of randomly arranged, irregularly shaped islands. Once the islands have formed, precursors for gallium nitride are introduced. Using this technique, it is also possible to reduce the defect densities of gallium nitride film, but threading dislocation densities on the order of about 10⁷ to about 10⁹ cm⁻² persist.

The conventional fabrication techniques described above provide reduced defect gallium nitride layers. However, what is desired is a fabrication technique capable of producing a high quality gallium nitride film having dislocations less than about 10⁷ cm⁻². It is therefore of great interest to produce wide bandgap thin film materials, such as gallium nitride, that contain as low a level of extended defects as possible. Further, what is desired is to introduce regular arrays in order to control the size, shape and orientation at the nanoscale and lead to defect reduction as close to the interface as possible. Ultimately, what is desired is to produce thin films on a silicon substrate that may be used in conjunction with CMOS circuitry.

### BRIEF SUMMARY OF THE INVENTION

The present invention describes methods for fabricating low defect wide bandgap thin films, such as gallium nitride. The present invention uses lithographically defined nanoscale features with structures that are well oriented with respect to specific substrate crystallographic axes, such that vertical and lateral growth rates are optimized. The methods of the present invention apply to wide bandgap semiconductor films and any film-substrate combination where significant lattice and thermal expansion misfit occurs.

One advantage of the methods of the present invention is that the nanoscale features may be aligned with specific crystallographic axes to allow for controlled growth rates. This may lead to a greater than four orders of magnitude decrease in the threading dislocation density in wide bandgap and other semiconducting thin films, and thus improved optical and electrical transport properties. This may also facilitate the growth of such materials on silicon such that direct integration with CMOS electronics is possible.

In one embodiment, the present invention provides a method of fabricating a semiconductor structure comprising using nanolithography to create an array of nanoscale features in a semiconductor masking layer and growing a semiconductor film within the nanoscale features on exposed areas of a substrate. The semiconductor film by this method may have a defect density less than 10⁶ cm², as compared to a semiconductor film grown using the standard epitaxial lateral overgrowth technique.

In another embodiment, the present invention provides a method of fabricating a semiconductor film comprising providing a substrate material compatible with the growth of a semiconductor layer, depositing an inorganic mask layer directly onto the substrate, depositing a block copolymer film onto the inorganic mask layer, etching the block copolymer film to leave an array of nanoscale features, etching the underlying inorganic mask layer to leave the array of nanoscale features, and growing the semiconductor film on exposed areas of the substrate epitaxially within the nanoscale features.

The nanoscale features comprise a cylindrical, spherical, striped or a complex shape. Preferably, each of the nanoscale features range in diameter from 1 nm to 100 nm, more preferably, from 5 nm to 50 nm, even more preferably, from 20 nm to 35 nm.

Substrate materials may comprise an inorganic crystallization growth substrate, such as aluminum oxide (sapphire), silicon, silicon carbide, gallium arsenide or any other substrate capable of supporting crystal growth on at least a portion of the exposed areas of the surface of the substrate. An inorganic mask layer may comprise silicon nitride and silicon oxide. A block copolymer may comprise polystyrene-polyisoprene (PS-PI), polystyrene-polybutadiene (PS-PB) or polystyrene-polemethylmethacrylate (PS-PMMA). A semiconductor layer may comprise gallium nitride, indium gallium nitride, silicon carbide, gallium arsenide, or zinc oxide.

In a further embodiment, the present invention provides a method for fabricating a semiconductor film on a selected substrate comprising providing a substrate material compatible with the growth of a semiconductor layer, growing a defective buffer layer directly on top of the substrate material, etching the defective buffer layer to leave an array of nanoscale features, and growing the semiconductor film epitaxially within the nanoscale features. The embodiment may further comprise depositing an inorganic mask layer directly on top of the defective buffer layer, etching the inorganic mask layer to leave an array of nanoscale features, and growing the semiconductor film on exposed areas of the substrate epitaxially within the nanoscale features.

In a still further embodiment, the present invention provides a semiconductor structure with reduced defects comprising an underlying layer comprising a pattern of nanoscale features, wherein the underlying layer comprises a dislocation density greater than 10⁹ cm⁻², and a semiconductor film nucleated within the plurality of nanoscale features, wherein the semiconductor film comprises a dislocation density less than 10⁶ cm⁻².

### BRIEF DESCRIPTION OF THE DRAWINGS

A variety of specific embodiments of this invention will now be illustrated with reference to the Figures. In these Figures, like elements have been given like numerals.

FIG. 1 is a perspective view illustrating a nanopatterned mask layer in accordance with an exemplary embodiment of the present invention;

FIG. 2 is a cross-sectional view illustrating a nanopatterned mask layer in accordance with an exemplary embodiment of the present invention;

FIG. 3 is a cross-sectional view illustrating a nanopatterned mask layer deposited on top of a buffer layer in accordance with an exemplary embodiment of the present invention;

FIG. 4 is a cross-sectional view illustrating a nanopatterned defective buffer layer in accordance with an exemplary embodiment of the present invention;

FIG. 5 is a cross-sectional view illustrating a nanopatterned substrate layer in accordance with an exemplary embodiment of the present invention; and

FIG. 6 is a graph illustrating dislocation density versus nanoisland width in accordance with an exemplary embodiment of the present invention.

### DETAILED DESCRIPTION OF THE INVENTION

As required, detailed embodiments of the present invention are disclosed herein, however, it is to be understood that the disclosed embodiments are merely exemplary of the invention that may be embodied in various and alternative forms. Specific structural and functional details disclosed herein are not to be interpreted as limiting, but merely as a basis for the claims as a representative basis for teaching one skilled in the art to variously employ the present invention. Throughout the drawings, like elements are given like numerals. The methods described below apply to wide bandgap semiconductor films, however, in principle also apply to any film-substrate combination where significant lattice and thermal expansion misfit occurs.

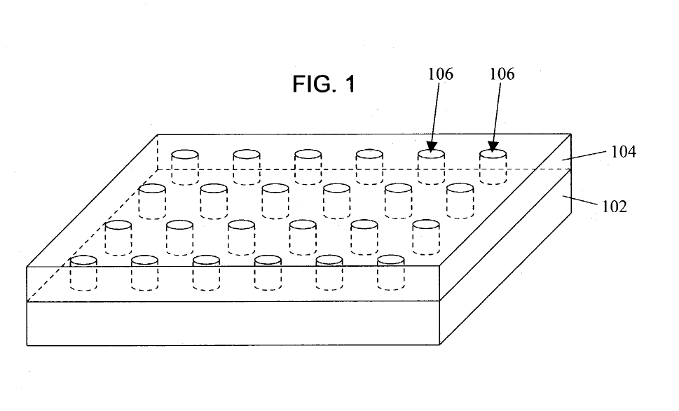

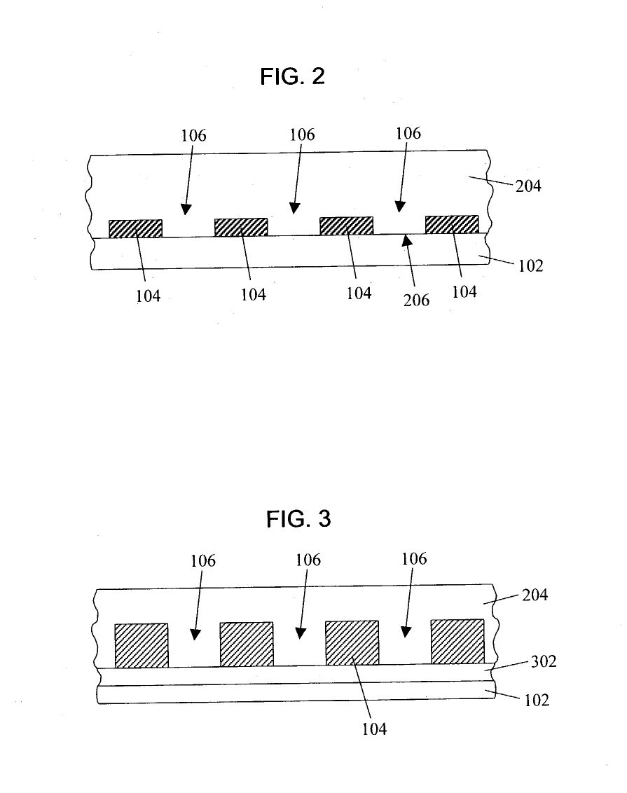

Referring now to FIG. 1, substrate 102 has inorganic mask layer 104 deposited on the surface of substrate 102. Inorganic mask layer 104 comprises lithographically defined nanoscale features 106 with structures, such as cylinder shaped features, that may or may not be well oriented with respect to specific substrate crystallographic axes. FIGS. 2-5 are illustrations of a cross-sectional view of FIG. 1, and further comprising various additional features.

Referring now to FIG. 2, one embodiment of a method for fabricating a low defect gallium nitride layer is illustrated. Substrate 102 comprises an inorganic crystallization growth substrate, such as sapphire, aluminum oxide, silicon, silicon carbide, gallium arsenide or any other substrate capable of supporting crystal growth on at least a portion of exposed area of the surface of substrate 102. Substrate 102 does not have to be planar. Single crystal substrates have been found to produce the highest quality material. Inorganic mask layer 104 is deposited and formed directly on inorganic crystallization growth substrate 102. The inorganic mask layer 104, for example, may comprise silicon nitride or silicon oxide. In one example, the inorganic mask layer 104 is deposited onto the substrate 102. The inorganic mask layer is then patterned using nanolithography, such as block copolymer nanolithography.

Phase morphology may be controlled by selecting a proper block copolymer type and molecular weight such that spherical, cylindrical or more complex nanoscale morphology is obtained. Block copolymers comprise amphiphilic components that are attached by covalent bonding. Examples, include, but are not limited to, linear diblock, triblock, multi-block copolymers, star copolymers and graft copolymers. Appropriate compositions of block copolymer films that may be used in practicing the present invention comprise polystyrene-polyisoprene (PS-PI), polystyrene-polybutadiene (PS-PB) and polystyrene-polemethylmethacrylate (PS-PMMA) synthesized using living anionic, nitroxide mediated or atom transfer radical polymerization techniques. The block copolymer film is selected as the template or mask for nanolithography. The block copolymer film is removed before growth of the final gallium nitride film.

The block copolymer film is spun onto the substrate containing the inorganic mask layer 104 and allowed to self-assemble. A typical time and temperature may be for about 24 hours at about 120° C. to about 180° C. Spin coating provides a rapid means for producing uniform and reproducible thin films over large areas of the selected substrate 102.

To eventually nanopattern the inorganic mask layer 104, first, a selected component of the block copolymer thin film is physically removed or chemically modified to produce a lithographic mask. A first component of the block copolymer is a polymer that is strongly resistant to a particular reactive etching process, while a second component of the block copolymer is easily etched away. The block copolymer film is exposed to chemical or photochemical processes such that one of the phases of the block copolymer is removed or modified, leaving behind an array of nanoscale features 106, such as cylinders, holes, posts or more complex shapes etched in the film. The nanoscale features 106 serve as a mask for a subsequent reactive etching process of the inorganic layer 104, as is described below. The block copolymer phase (or component) may be removed or modified by a variety of techniques, such as by exposure to a UV light source, an ozonation process or stained with a heavy metal (e.g. ruthenium or osmium tetroxide).

With respect to UV exposure, the first component of the block copolymer may have a response to radiation. For example, if a first component of the block copolymer becomes degraded upon exposure to radiation (i.e., undergoes chain scission) while the second component of the block copolymer is mainly unaffected, then the first component may be removed with a selective solvent, leaving behind the second component. It is known that PMMA can be degraded effectively by exposure to an electron-beam or ultraviolet light, while PS is known to be much more stable. Subsequent to UV exposure, acetic acid may be used to remove the degraded PMMA.

With respect to osmium tetroxide, selective chemistry may be used to chemically modify one or more block copolymer components in order to alter the etching rate. For example, the polyisoprene (PI) component of PS-PI and the polybutadiene (PB) block of PS-PB may be selectively modified using vapors of osmium tetroxide, an aggressive staining agent that deposits osmium tetroxide on the diene carbon-carbon double bonds. This heavy metal reduces the etch rate of the diene component in a 10:1 CF₄:O₂ plasma. The PS component etches twice as fast as the PI component.

In the case of the silicon nitride or silicon oxide mask layer, a reactive ion etch (RIE) may be used to etch the underlying silicon oxide or silicon nitride film, leaving behind an inorganic film 104 having the array of nanoscale features etched within it. The RIE is performed using CHF₃/Ar, CHF₃, CF₄, SF₆, or another gas chemistry as the etchant. As is known in the art, in RIE, the substrate is placed inside a reactor in which several gases are introduced. A plasma is struck in the gas mixture using an RF power source, breaking the gas molecules into ions. The released ions are then accelerated towards, and react at, the surface of the underlying silicon oxide or silicon nitride film being etched, forming another gaseous material. This is typically known as the chemical part of reactive ion etching. The physical part of RIE is similar in nature to the sputtering deposition process. If the ions possess enough energy, the ions knock atoms out of the film to be etched without a chemical reaction. It is important to develop dry etch processes that balance chemical and physical etching. By changing the balance, it is possible to influence the anisotropy of the etching, since the chemical part is isotropic and the physical part is highly anisotropic. The combination is capable of forming nanoscale feature sidewalls having shapes varying from rounded to vertical.

In an alternative embodiment, a subclass of RIE known as deep RIE (DRIE) may be practiced. In DRIE, etch depths of hundreds of microns may be achieved with almost vertical nanoscale feature sidewalls. The process comprises alternating two different gas compositions in the reactor. The first gas composition creates a polymer on the surface of the underlying inorganic mask layer 104. The second gas composition etches the underlying inorganic mask layer 104. The polymer is immediately sputtered away by the physical portion of the etching, but only on the horizontal surfaces, not on the sidewalls. Because the polymer dissolves very slowly in the chemical part of the etching, it builds up on the sidewalls and protects them from etching. As a result, etching aspect ratios of 50:1 may be achieved.

Still referring to FIG. 2, the etched inorganic mask layer 104 is used as a template for growth of a desired wide bandgap thin film 204, examples of which comprise gallium nitride, indium gallium nitride, silicon carbide, zinc oxide and other thin films. Gallium nitride will be used for purposes of this discussion, however, it is understood that various alternative thin films may be used. The thin film 204 is grown to cover the exposed substrate surface 206. The gallium nitride does not nucleate on the mask layer 104, but grows on the interface with the substrate within the nanopatterned features 106. The gallium nitride is epitaxially grown within the features 106. The two main stages of lateral epitaxy are vertical growth and lateral growth. During vertical growth, the deposited gallium nitride grows selectively within the nanopatterned features 106 due to the much higher sticking coefficient of the gallium atoms on the substrate surface compared to the inorganic mask surface. The gallium or nitrogen atoms should not readily bond to the mask surface in numbers and for a time sufficient cause gallium nitride nuclei to form. The gallium nitride eventually grows over the top of the mask layer 104, with gallium nitride crystal facets on neighboring growth areas coming into contact with each other. By further continuing the epitaxial growth, a continuous thin film of gallium nitride semiconductor layer is formed. While this is one mechanism for defect reduction using this process, it is also possible that dislocation reactions leading to annihilation may be induced within or some distance above the nanoscale features, much like the conventional mechanism described above in paragraph (0006).

The wide bandgap thin film 204 produced possesses a reduced defect density, primarily with respect to threading dislocations, as compared to the defect reduction scheme of lateral epitaxial overgrowth without nanopatterned features 106. Growing a gallium nitride crystal on a sapphire substrate, without the nanopatterned features 106 of the present invention, produces a greater amount of stress (strain energy) that leads to dislocations within the gallium nitride film. Also, without the nanopatterned features 106, threading dislocations associated with a buffer layer previously grown on the crystal substrate extend to the gallium nitride film 204. However, if the buffer layer is composed of a different material than the film, e.g. aluminum nitride, it is possible for dislocations to be trapped at the interface due to the energy cost associated with traversing that interface. Multiple buffer layers of a different material than the final film may be combined with nanolithography to further reduce defects. Nevertheless, by growing the gallium nitride film 204 within a laterally confined space, the nucleation of dislocations is suppressed, leading to the ability to grow a thicker film before dislocations become significant.

The nanoscale features 106 etched in the masking layer may be of a uniform cylindrical, spherical, striped or more complex shape. Preferably, the diameter of one cylindrical opening has a size ranging from about 1 nm to about 100 nm, more preferably, from about 5 nm to about 50 nm, even more preferably, from about 20 nm to about 40 nm. The limiting factor in the diameter of the cylindrical opening is based on being able to get reactants into the opening in order to nucleate down onto the substrate and allowing for transport of reaction products out of the nanoscale features. The height of the cylindrical openings, i.e., the distance from the substrate interface to the top of the masking layer is preferably from about 5 nm to about 1000 nm, more preferably, from about 10 nm to about 500 nm, even more preferably, from about 25 nm to about 100 nm. The dimension between individual nanopatterned features is from about 15 nm to about 25 nm, more preferably, from about 25 nm to about 75 nm, even more preferably, from about 75 nm to about 500 nm.

The thickness of the substrate 102 is typically 200 μm to about 600 μm. The inorganic mask layer thickness ranges from about 5 nm to about 1000 nm, more preferably from about 25 nm to about 200 nm, even more preferably, from about 50 nm to about 100 nm. The gallium nitride film thickness measured from the bottom of the feature opening, i.e., the substrate interface, ranges from about 0.1 μm to about 6 μm, more preferably, from about 0.25 μm to about 5 μm, even more preferably, from about 0.5 μm to about 5 μm.

The inorganic mask layer 104 may comprise silicon oxide, silicon nitride, tungsten or any other material that does not react with gallium nitride. It is preferred to use an inorganic mask layer 104 that is able to withstand microfabrication processes in the range of about 800° C. to about 1100° C.

Referring now to FIG. 3, a further embodiment of a method of the present invention is illustrated. In this method, the inorganic mask layer 104, such as silicon nitride or silicon oxide, is deposited on top of a buffer layer 302 already grown on the crystallization growth substrate 102. The buffer layer 302, for example, may comprise a thin and highly defective gallium nitride buffer film, or any other compatible hetero-epitaxial semiconductor material, such as zinc oxide, silicon carbide, or aluminum nitride. As with the embodiment illustrated in FIGS. 1 and 2, the crystallization substrate 102 may be a single crystal substrate, such as a single crystal of sapphire, silicon, silicon carbide or other semiconductor, or any other substrate capable of supporting crystal growth on at least some exposed area of the surface.

The buffer layer 302 may be defective, comprising threading dislocations of approximately 10¹⁰ cm⁻². The gallium nitride layer 204 is grown within the nanopatterned features 106 of the mask layer 104, and on top of the patterned defective gallium nitride buffer layer 302. The gallium nitride layer 204 has the same lattice parameter as the defective buffer layer 302. Multiple buffer layers may be used, such as buffer layer, masking layer, buffer layer, masking layer, essentially reducing the grade of defect density on each subsequent layer. This results in the final buffer layer having a lower defect density than the first buffer layer. The gallium nitride film 204 is then grown.

In another embodiment, it is also possible to use a block copolymer with one of the phases being a pre-ceramic phase that is converted to silicon oxide or another inorganic upon annealing. The converted ceramic phase may act as a nanoscale mask directly during the final wide bandgap film growth, such that an intermediate silicon oxide or silicon nitride film is not required.

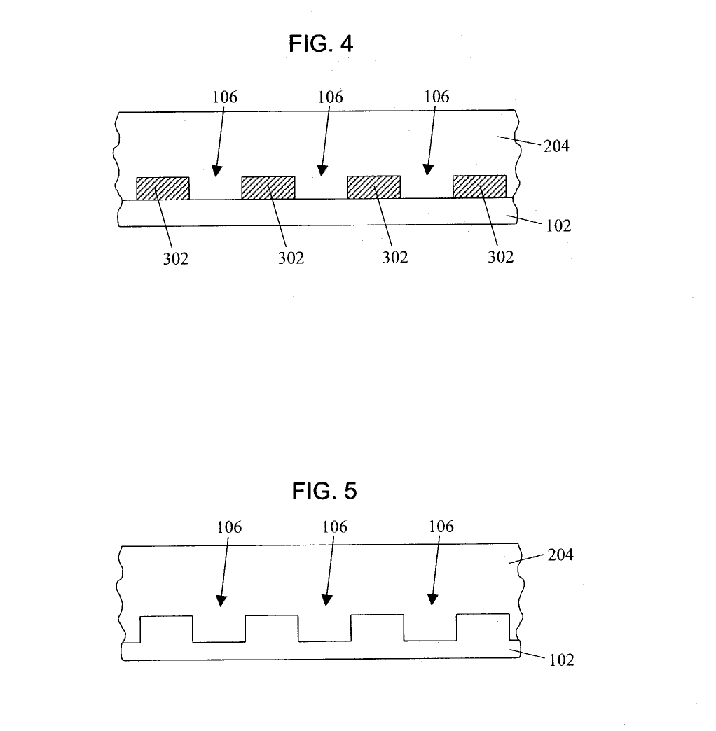

Referring now to FIG. 4, in another embodiment, the buffer layer 302 grown on the crystallization growth substrate 102 may be nanopatterned. As stated above, the buffer layer 302 may comprise a thin and highly defective gallium nitride buffer film, or any other compatible hetero-epitaxial semiconductor material, such as silicon carbide or aluminum nitride. As with the embodiments illustrated in FIGS. 1-3, the crystallization substrate 102 may be a single crystal substrate, such as a single crystal sapphire, silicon, silicon carbide or other semiconductor, or any other substrate capable of supporting crystal growth on at least some exposed area of the surface.

As is the case with FIG. 3, the buffer layer 302 may be defective, comprising threading dislocations of approximately 10¹⁰ cm⁻². The gallium nitride layer 204 is grown within the nanopatterned features 106 of the defective buffer layer 302. In one example, the gallium nitride layer 204 has the same lattice parameter as the defective buffer layer 302.

Referring now to FIG. 5, in another embodiment, the substrate 102 itself may be nanopatterned. The nanofeatures are etched through the buffer layer 302 and into the substrate 102. The buffer layer 302 remains on the surface of the substrate as mesas. The gallium nitride film 204 is then grown over the whole structure. As stated above, the buffer layer 302 may comprise a thin and highly defective gallium nitride buffer film, or any other compatible hetero-epitaxial semiconductor material, such as silicon carbide or aluminum nitride.

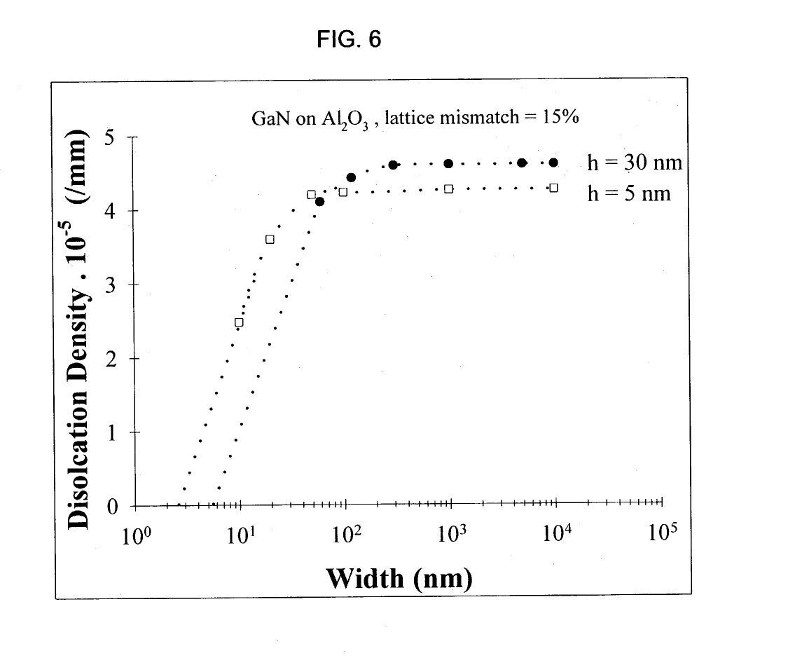

A common feature among FIGS. 1-5 is that a gallium nitride film is nucleated within nanopatterned features 106. Nucleating within nanopatterned features results in a change in the dislocation nucleation process, due to a change in the stress distribution in the gallium nitride film compared to the conventional ELO case. This is displayed in FIG. 6, were a decrease in the overall dislocation density and an increase in the critical dimension for the introduction of dislocations is observed as a function of feature size and aspect ratio. Reducing the strain energy in the system reduces the dislocation density in the overgrown film. Other features common among FIGS. 1-5 is that the nanopatterned features may be ordered or randomly dispersed in the plane, and aligned with the substrate crystallographic axes. Random and ordered features are both well defined. The feature shape remains constant throughout the distribution, but there may not be any periodicity.

In alternative embodiments, the nanopatterned features may be introduced using variations of nanolithography, the art and science of etching, writing, and printing at the microscopic level, where the dimensions of features are on the order of nanometers. Variations of nanolithography that may be employed by the present invention comprise electron-beam (e-beam) lithography, imprint nanolithography, nanoembossing, block copolymer nanolithography and combinations thereof. Nanoimprint lithography may be used to produce repeatable patterns of well-defined shapes oriented along a specific crystallographic orientation. A technique may be selected based on a desired specific feature order. Various compositions may be used to obtain predetermined features shapes. In a further embodiment, microlithography may be used to fabricate mesas on the substrate prior to block copolymer film deposition, so as to align the major axes of a block copolymer phase along a specific crystallographic direction of the growth substrate by a mechanism known as graphoepitaxy. This alignment helps to control the growth rate, morphology and defect density in the final film. The morphological development in overgrown films has been shown to be a function of feature orientation in convenioteial ELO. Furthermore, the mesa structures fabricated to promote graphoepitaxy also act as a conventional ELO mask, such that the combined effect of micron scale and nanoscale defect reduction occurs.

The high quality thin film produced using the methods of the present invention comprises dislocation densities less than about 10⁹ cm⁻², as opposed to conventional fabrication techniques producing dislocations on the order of about 10⁹ cm⁻² to about 10¹¹ cm⁻². In the preferred embodiments, dislocations produced by the present invention range from about 10⁴ cm⁻² to about 10⁹ cm⁻², more preferred, from about 10² cm⁻² to about 10⁶ cm⁻².

The fabrication methods of the present invention comprise processing the substrate before the gallium nitride is introduced. A working example of the fabrication method involves use of a c-plane sapphire (0001) orientation substrate. A low temperature gallium nitride buffer layer is grown on the sapphire by a hydride vapor phase epitaxy (HVPE) or metal oxide chemical vapor deposition (MOCVD) process. Typical HVPE precursors for gallium nitride are gallium chloride (formed by reacting gallium with hydrochloric acid) and ammonia. Typical gallium nitride precursors for MOCVD are trimethylgallium (TMG) and ammonia. A typical growth temperature for the gallium nitride buffer layer is about 550° C. This is followed by the in situ deposition of silicon nitride using silane and ammonia, or silicon oxide in a separate furnace by low-pressure chemical vapor deposition (LPCVD). A 50 nm thick random brush polymer thin film is spun onto the substrate (containing the buffer layer and mask layer) from a toluene solution, baked at a temperature of about 160-180° C. for about 1-24 hours, and washed with toluene. A 40 nm thick block coplymer thin film is then spun onto the random brush and allowed to self assemble for about 24 hrs at about 170° C. The film is then exposed to UV light, developed in acetic acid, and then placed in a reactive ion etching (RIE) machine (e.g. Plasmatherm Inc.). Etching mat be achieved in CF4, CHF3, SF6, or a mixture of the above with argon or oxygen. The remaining polymer film is then removed, the substrate is placed back in the HVPD or MOCVD chamber, and the subsequent gallium nitride film growth occurs, typically at about 800-1100° C.

In a second working example, a low temperature gallium nitride buffer layer is deposited on a silicon substrate. A block copolymer thin film is spun onto the substrate (containing the buffer layer) and self-assembled at a suitable temperature and time. The majority phase of the block copolymer is an organic precursor to silicon oxide. Silicon oxide is formed by a suitable heat treatment and the film is developed by a suitable method (UV exposure, ozone, etc.). No intermediate inorganic mask layer or RIE process is required in this example. The subsequent gallium nitride film is grown directly through the nanoscale features present in the silicon oxide.

The methods of the present invention described above are used to produce semiconductor materials and devices, such as high quality thin films for many electronic and optoelectronic applications, including high temperature electronic devices, high-power microwave circuits, transistors, blue-light-emitting diodes, multi-layer quantum well laser devices, and sensors.

It is apparent that there have been provided, in accordance with the systems and methods of the present invention, techniques for fabricating low defect wide bandgap thin films. Although the systems and methods of the present invention have been described with reference to preferred embodiments and examples thereof, other embodiments and examples may perform similar functions and/or achieve similar results. All such equivalent embodiments and examples are within the spirit and scope of the present invention and are intended to be covered by the following claims.

What is claimed is:

1. A method of fabricating a semiconductor structure comprising:
using nanolithography to create an array of nanoscale features in a semiconductor masking layer; and
growing a semiconductor film within the nanoscale features on exposed areas of a substrate;
wherein the semiconductor film has a defect density less than 10⁶ cm⁻²;
wherein each of the nanoscale features range in diameter from 1 nm to 40 nm.

2. The method of claim 1, wherein the nanoscale features are well oriented with respect to specific substrate crystallographic axes such that vertical and lateral semiconductor film growth rates are controlled.

3. A method of fabricating a semiconductor film, comprising:
providing a substrate material compatible with the growth of a semiconductor layer;
depositing an inorganic mask layer directly onto the substrate;
depositing a block copolymer film onto the inorganic mask layer;
etching the block copolymer film to leave an array of nanoscale features;
etching the underlying inorganic mask layer to leave the array of nanoscale features; and
growing the semiconductor film on exposed areas of the substrate epitaxially within the nanoscale features.

4. The method of claim 3, wherein the semiconductor film fabricated comprises a dislocation density less than or equal to 10⁹ cm⁻².

5. The method of claim 3, wherein the semiconductor film fabricated comprises a dislocation density less than or equal to 10⁶ cm⁻².

6. The method of claim 3, wherein the nanoscale features comprise one of the following uniform shapes: cylindrical, spherical, striped and a complex shape.

7. The method of claim 3, wherein each of the nanoscale features range in diameter from 1 nm to 100 nm.

8. The method of claim 3, wherein each of the nanoscale features range in diameter from 5 nm to 50 nm.

9. The method of claim 3, wherein the nanoscale features are aligned with specific substrate crystallographic axes to allow for controlled growth rates of the semiconductor film.

10. The method of claim 3, wherein the substrate material comprises one of the following: an inorganic crystallization growth substrate, sapphire, aluminum oxide, silicon, silicon carbide, gallium arsenide and any other substrate capable of supporting crystal growth on at least a portion of exposed area of a surface of the substrate.

11. The method of claim 3, wherein the inorganic mask layer comprises one of the following: silicon nitride and silicon oxide.

12. The method of claim 3, wherein the block copolymer is selected from the group consisting of: polystyrene-polyisoprene (PS-PI), polystyrene-polybutadiene (PS-PB) and polystyrene-polemethylmethacrylate (PS-PMMA).

13. The method of claim 3, wherein the semiconductor layer comprises one of the following: gallium nitride, indium gallium nitride, silicon carbide and zinc oxide.

14. The method of claim 3, wherein the distance between individual nanoscale features is from 1 nm to 100 nm.

15. The method of claim 3, wherein the distance between individual nanoscale features is from 30 nm to 50 nm.

16. The method of claim 3, wherein mesa structures fabricated to promote graphoepitaxy act as a conventional epitaxial lateral overgrowth mask such that a combined effect of micron scale and nanoscale defect reduction occurs.

17. The method of claim 3, wherein subsequent gallium nitride film is grown directly through the nanoscale features present in the silicon oxide.

18. A method of fabricating a semiconductor film on a selected substrate comprising:
providing a substrate material compatible with the growth of a semiconductor layer;
growing a defective buffer layer directly on top of the substrate material;
etching the defective buffer layer to leave an array of nanoscale features; and
growing the semiconductor film epitaxially within the nanoscale features.

19. The method of claim 18, further comprising:
depositing an inorganic mask layer directly on top of the defective buffer layer;
etching the inorganic mask layer to leave an array of nanoscale features; and
growing the semiconductor film on exposed areas of the substrate epitaxially within the nanoscale features.

20. The method of claim 18, wherein the buffer layer comprises one of the following: a defective gallium nitride buffer film, gallium arsenide on silicon, silicon carbide film on sapphire, aluminum nitride and any other hetero-epitaxial semiconductor system.

21. The method of claim 18, wherein the defective buffer layer comprises a dislocation density of about 10¹⁰ cm⁻².

22. The method of claim 19, wherein the steps of depositing a defective buffer layer and depositing an inorganic mask layer are repeated for a pre-determined amount of times for the purpose of reducing a grade of defect density on each subsequent buffer layer.

23. The method of claim 18, wherein the semiconductor film fabricated comprises a dislocation density less than or equal to 10⁹ cm⁻².

24. The method of claim 18, wherein the semiconductor film fabricated comprises a dislocation density less than or equal to 10⁶ cm^{-2.}

25. The method of claim 18, wherein the nanoscale features comprise one of the following uniform shapes: cylindrical, spherical, striped and a complex shape.

26. The method of claim 18, wherein each of the nanoscale features range in diameter from 1 nm to 100 nm.

27. The method of claim 19, wherein the nanoscale features are well oriented with respect to specific substrate crystallographic axes such that vertical and lateral semiconductor film growth rates are controlled.

28. A semiconductor structure with reduced defects comprising:
an underlying layer comprising a pattern of nanoscale features, wherein the underlying layer comprises a dislocation density greater than 10⁹ cm⁻²; and
a semiconductor film nucleated within the plurality of nanoscale features, wherein the semiconductor film comprises a dislocation density less than 10⁶ cm⁻².

29. The structure of claim 28, wherein the nanoscale features are well oriented with respect to specific underlying layer crystallographic axes such that vertical and lateral semiconductor film growth rates are controlled.

30. The structure of claim 28, wherein the nanoscale features comprise one of the following uniform shapes: cylindrical, spherical, striped and a complex shape.

31. The structure of claim 28, wherein each of the nanoscale features range in diameter from 1 nm to 100 nm.

32. The structure of claim 28, wherein each of the nanoscale features range in diameter from 5 nm to 50 nm.
